(19) United States
(12) Patent Application Publication
(10) Pub. No.: US 2001/0024137 A1
(43) Pub. Date: Sep. 27, 2001

(54) Driver circuit

(75) Inventor: Keiji Miura, Tokyo (JP)

Correspondence Address: Paul J. Esatto, Jr., Scully, Scott, Murphy & Presser, 400 Garden City Plaza, Garden City, NY, 11530, US

(73) Assignee: NEC Corporation, Tokyo (JP)

(21) Appl. No.: 09/804,327

(22) Filed: Mar. 12, 2001

(30) Foreign Application Priority Data
Mar. 14, 2000 (JP) 2000-070642

(51) Int. Cl. H03L 5/00

(52) U.S. Cl. 327/333

(57) ABSTRACT

In a driver circuit, a signal from an internal circuit region is shifted by a differential circuit formed by NMOS transistors N4, N5, N6 and resistors R1, R2, output signals from the differential circuit being input to an output stage formed by NMOS transistors N1, N2, N3 and resistors R3, R4.

### BACKGROUND OF THE INVENTION

1. Field of the Invention

The present invention relates to a driver circuit, and more particularly to a driver circuit suitable for LOW Voltage Differential Swing (LVDS) for use in high speed small-amplitude signal transmission.

2. Related Art

In a CMOS integrated circuit which is required to transmit high-speed signals with operating frequencies of several hundreds of megahertz, from the standpoint of reduction of EMI noise and operating margin and the like, a resistively terminated constant-current drive differential output circuit is widely used. In a drive circuit of the past, such as shown in FIG. 4, when a high-level signal is applied to an input terminal 41 and a low-level signal is applied to an input terminal 40, an inverter formed by the PMOS transistor P45 and the NMOS transistor N47 outputs a low level that is at the same potential as the ground level, and an inverter formed by the PMOS transistor P46 and the NMOS transistor N48 outputs a high level that is the same potential as the power supply voltage, the switching transistor NMOS N1 being off and the switching transistor NMOS N2 being on. The transistor N3 is connected in current-mirror fashion to the other NMOS transistors, and has its gate voltage set so that the current thereof, I, flowing in the transistor N2. In this condition, current does not flow in the resistance R3, the positive-phase output terminal 1 being therefore at the same potential as the external terminating power supply VDDE, and the inverted-phase output terminal 2 outputting a low level signal of (VDDE−I×R4). If a low level is applied to the input signal terminal 41 and a high level is applied to the input signal terminal 40, the inverter formed by the PMOS transistor P45 and the NMOS transistor N47 outputs a high level of the same potential as the power supply voltage, and the inverter formed by the PMOS transistor P46 and the NMOS transistor N48 outputs a low level of the same potential as the ground potential, so that the NMOS N1 is on and the NMOS N2 is off. As a result, the constant current I established by the NMOS transistor N3 by supplying a fixed voltage to the gate thereof flows in the transistor N1, so that positive-phase output terminal 1 outputs a low-level signal of (VDDDE−I×R3), current not flowing in the resistance R4, and the inverted-phase output terminal 2 outputting a high-level signal having a potential that is the same as the external termination power supply VDDE. The input voltage of the output circuit in FIG. 4 during switching is VDDI/2 as shown by the broken line of FIG. 5, and the drain voltage VDc of the constant-current power supply N3 being expressed as in the following Equation (1), when a gate-to-source voltage of the transistor N1 is Vgns1.

VDc=VDDI/2−Vgns1 (1)

The drain voltage VDd of the constant-current transistor N3 for differential input is given by the following equation.

VDd=VDDI−Vgns1 (2)

If the drain capacitance of the transistor N3 is C, the amount of charge that is discharged because of a change in the drain potential when changing from differential operation to common mode operation is given by the following equation.

ΔQ =C×ΔVD=C×(VDDI/2) (3)

In high-speed transmission lines, a characteristic impedance Zo of 50 Ω is widely used, so that R3 and R4 is 50 Ω, respectively, and if the output amplitude is set so as to be approximately 500 mV, the output current is 10 mA. Because the constant current flowing in transistor N3 is generally supplied by a current mirror circuit, in order to given emphasis on the relative accuracy of the current mirror transistors, the gate length of the transistor is made long. Therefore, the current is a large value of 10 mA, and the gate length is made long, so that the constant-current supply transistor N3 becomes extremely large, thereby making the drain capacitance thereof large.

A first problem with the above-noted technology is that, although at a frequency in the region of 400 MHz it is possible to achieve sufficient drive of an external load with a current of approximately 3 to 4 mA, when the frequency exceeds approximately 1 GHz, in order to drive an external load using a constant-current type driver circuit at a high speed, a current of approximately 10 mA is necessary, making it necessary to make the size of the transistor for constant-current supply of the output stage large. The effect of this is that, when the same voltage is input to both gates of the switching transistor N1, N2, as shown in FIG. 5, the drain voltage of the constant-current supply transistor N3 drops, so that the constant-current supply transistor N3 operates in the non-saturated region, resulting in disturbance to the constant-current supply characteristics thereof, or the need for a charging current for the above-noted drain, capacitance C, so that both of the differential switching transistors go into the on condition, causing waveform distortion.

A second problem is that, with a decrease in the voltage of transistors, the power supply voltage of the first stage making up the logic circuit is reduced, and if the power supply voltage of the first stage making up the logic circuit is low in comparison with the output stage power supply voltage, there is a further reduction in the voltage input to the switching transistors, the result of which is that the drain voltage of the constant-current supply transistor is lowered.

The LOW Voltage Differential Swing (LVDS) I/O buffer driver is described in the Japanese unexamined patent publication (KOKAI) No. 11-85343 corresponding to U.S. patent application Ser. No. 08/882827. However, this circuit does not solve above-noted problem.

Accordingly, it is an object of the present invention to improve on the above-noted drawbacks in the prior art, by providing a novel driver circuit that, by maintaining a high drain voltage of the constant-current supply transistor of the output stage, causes this constant-current supply transistor to operate in the saturated region at all times, so as to improve the waveform quality of a CMOS differential driver circuit for high-speed current driving and improve the transmission characteristics.

### SUMMARY OF THE INVENTION

To achieve the above-noted objects, the present invention adopts the following base technical constitution.

Specifically, the first aspect of the present invention is a driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of the first N-channel MOS transistor and a source of the second N-channel MOS transistor, a first resistor connected between the first power supply and the drain of the first N-channel MOS transistor, a second resistor connected between the first power supply and the drain of the second N-channel MOS transistor, wherein the driver circuit comprising; a first power supply of the driver circuit, a first resistor connected between the first power supply of the driver circuit and a gate of the first N-channel MOS transistor of the output stage, a second resistor connected between the first power supply of the driver circuit and a gate of the second N-channel MOS transistor, a first N-channel MOS transistor, a drain of which is connected to a gate of the first N-channel MOS transistor of the output stage, a gate of which is connected to a first input terminal, a second N-channel MOS transistor, a drain of which is connected to a gate of the second N-channel MOS transistor of the output stage, a gate of which is connected to a second input terminal, and a third N-channel MOS transistor, a source of which is connected to ground, a gate of which is connected to a second power supply of the driver circuit, and a drain of which is connected to a source of the first N-channel MOS transistor of the driver circuit and a source of the second N-channel MOS transistor of the driver circuit.

In the second aspect of the present invention, a potential of the first power supply of the driver circuit is lower than that of the first power supply of the output stage.

The third aspect of the present invention is a driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of the first N-channel MOS transistor and a source of the second N-channel MOS transistor, a first resistor connected between the first power supply and the drain of the first N-channel MOS transistor, a second resistor connected between the first power supply and the drain of the second N-channel MOS transistor, wherein the driver circuit comprising; a first power supply of the driver circuit, a first P-channel MOS transistor, a gate of which is connected to a first input terminal, a drain of which is connected to ground, and a source of which is connected to a gate of the second N-channel MOS transistor of the output stage, a second P-channel MOS transistor, a gate of which is connected to a second input terminal, a drain of which is connected to ground, and a source of which is connected to a gate of the first N-channel MOS transistor of the output stage, a third P-channel MOS transistor, a source of which is connected to the first power supply of the driver circuit, a gate of which is connected to a second power supply of the driver circuit, and a drain of which is connected to a gate of the second N-channel MOS transistor of the output stage, and a fourth P-channel MOS transistor, a source of which is connected to the first power supply of the driver circuit, a gate of which is connected to the second power supply of the driver circuit, and a drain of which is connected to a gate of the first N-channel MOS transistor of the output stage.

### BRIEF DESCRIPTION OF THE DRAWINGS

FIG. 1 is a circuit diagram of a driver circuit according to a first embodiment of the present invention.

FIG. 2(a) is a circuit diagram of a driver circuit according to a second embodiment of the present invention.

FIG. 2(b) is a circuit diagram of a third power supply circuit according to a second embodiment of the present invention.

FIG. 3 is a circuit diagram of a driver circuit according to a third embodiment of the present invention.

FIG. 4 is a circuit diagram of a driver circuit of the past.

FIG. 5 is a graph showing the changes in potential of the transistor N3 of the present invention and of the prior art.

### DETAILED DESCRIPTION OF THE PREFERRED EMBODIMENTS

Embodiments of a driver circuit according to the present invention are described in detail below, with references being made to relevant accompanying drawings.

### First Embodiment

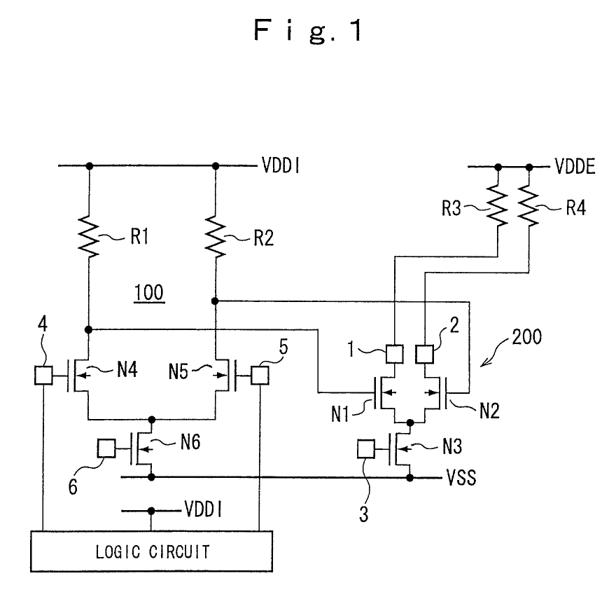

FIG. 1 is a circuit diagram showing a first embodiment of a driver circuit according to the present invention.

FIG. 1 shows a driver circuit 100 of an output stage 200 comprising a first power supply VDDE, a first N-channel MOS transistor N1, a drain of which is connected to a first output terminal 1, a second N-channel MOS transistor N2, a drain of which is connected to a second output terminal 2, and a third N-channel MOS transistor N3, a source of which is connected to ground VSS, a gate of which is connected to a second power supply 3, and a drain of which is connected to a source of the first N-channel MOS transistor N1 and a source of the second N-channel MOS transistor N2, a first resistor R3 connected between the first power supply VDDE and the drain of the first N-channel MOS transistor N1, a second resistor R4 connected between the first power supply VDDE and the drain of the second N-channel MOS transistor N2, wherein the driver circuit 100 comprising; a first power supply VDDI of the driver circuit 100, a first resistor R1 connected between the first power supply VDDI of the driver circuit 100 and a gate of the first N-channel MOS transistor N1 of the output stage 200, a second resistor R2 connected between the first power supply VDDI of the driver circuit 100 and a gate of the second N-channel MOS transistor N2, a first N-channel MOS transistor N4, a drain of which is connected to a gate of the first N-channel MOS transistor N1 of the output stage 200, a gate of which is connected to a first input terminal 4, a second N-channel MOS transistor N5, a drain of which is connected to a gate of the second N-channel MOS transistor N2 of the output stage 200, a gate of which is connected to a second input terminal 5, and a third N-channel MOS transistor N6, a source of which is connected to ground VSS, a gate of which is connected to a second power supply 6 of the driver circuit 100, and a drain of which is connected to a source of the first N-channel MOS transistor N4 of the driver circuit 100 and a source of the second N-channel MOS transistor N5 of said driver circuit 100.

In the present invention, the first power supply VDDI of the driver circuit 100 is used for the power supply of a logic circuit, and the potential of the first power supply VDDI of the driver circuit 100 is lower than that of the first power supply VDDE of the output stage, the input signal of the level-shifting circuit 100 being generated by a circuit using the second power supply VDDI.

The first embodiment of the present invention is described in further detail below.

Referring to FIG. 1, the first embodiment of the present invention has an internal circuit region (not shown in the drawing) forming a logic circuit and an external circuit region performing signal transmission and receiving with an external LSI device, the voltage of the power supply VDDI for the internal circuit region being lower than the voltage of the power supply VDDE for the external circuit region, and the gate oxide film of a MOS transistor for the external circuit region being formed thicker than the gate oxide film of a MOS transistor for the internal circuit region. The driver circuit has a differential output stage that causes current to flow externally and a resistive load type of differential circuit as a front-end stage thereof, the resistive load type differential circuit converting the signal level of the internal circuit region to a high potential with a small amplitude, outputting this to the differential output stage, so that compared with input of a signal having an amplitude of the power supply, as in the past, the potential variation is made small, thereby resulting in a configuration in which variation of the drain potential of the constant-current supplying transistor N3 of the output stage does not occur.

In a driver circuit configured as described above, the input terminal 4 is a positive-phase input terminal and the input terminal 5 is an inverted-phase input terminal, the high level of which is at the same potential as the power supply voltage VDDI of the internal circuit region, and the low level of which is at the ground potential. Transistors N3 and N6 are connected in current mirror fashion with the other NMOS transistors, respectively, and the gate potential thereof is set so that constant current flows, respectively. When a high level is input to the positive-phase input terminal 4 and a low level is input to the inverted-phase input terminal 5, the transistor N4 is switched on, and the transistor N5 is switched off. Therefore, the constant current I2 established by the transistor N6 flows in the transistor N4, and the drain potential of the transistor N4 is (VDDI−I2×R1). Because there is no current flowing in the transistor N5, the drain potential of the transistor N5 is VDDI, the transistor N1 is off, and the transistor N2 is on. Therefore, the constant current I1 established by the transistor N3 flows in the transistor N2, so that the positive-phase output terminal 1 is at the same potential as VDDE, thereby outputting a high logic level, and the inverted-phase output terminal 2 is at (VDDE−I1×R4), thereby outputting a low logic level.

The common-phase potential VDc during differential switching is given by Equation (4).

VDc={VDDI+(VDDI−I2×R1)}/2=VDDI−(I2×R1/2) (4)

Therefore, the drain potential VDd of the transistor N3 is given by the following equation.

VDd=VDc−Vgns1 (5)

If the drain capacitance of the transistor N3 is Cj, the amount of electrical charge discharged because of the change in the drain potential when changing to the common-mode operation from differential operation is expressed as follows.

Q=Cj×ΔVD=Cj×I2×R1/2 (6)

Therefore, as is clear from a comparison between Equation (3) and Equation (6), the change in the drain potential of the transistor N3 is greatly reduced, from (VDDI/2) to (I2×R1/2), thereby clearly achieving the object of the present invention.

### Second Embodiment

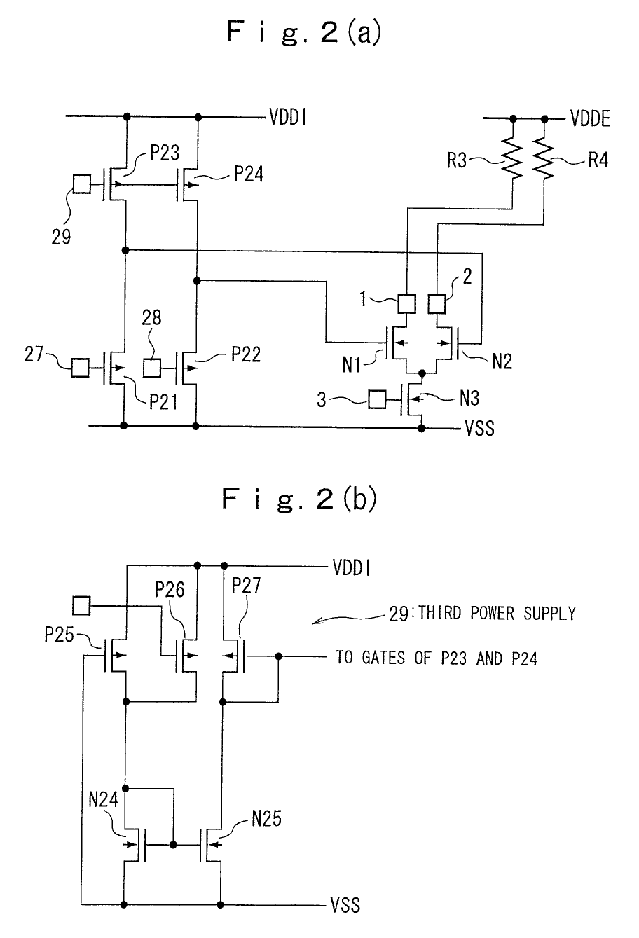

FIG. 2 shows a driver circuit according to a second embodiment of the present invention.

FIG. 2 shows a driver circuit 110 of an output stage 200 comprising a first power supply VDDE, a first N-channel MOS transistor N1, a drain of which is connected to a first output terminal 1, a second N-channel MOS transistor N2, a drain of which is connected to a second output terminal 2, and a third N-channel MOS transistor N3, a source of which is connected to ground VSS, a gate of which is connected to a second power supply 3, and a drain of which is connected to a source of the first N-channel MOS transistor N1 and a source of the second N-channel MOS transistor N2, a first resistor R3 connected between the first power supply VDDE and the drain of the first N-channel MOS transistor N1, a second resistor R4 connected between the first power supply VDDE and the drain of the second N-channel MOS transistor N2, wherein the driver circuit 110 comprising; a first power supply VDDI of the driver circuit 110, a first P-channel MOS transistor P21, a gate of which is connected to a first input terminal 27, a drain of which is connected to ground VSS, and a source of which is connected to a gate of the second N-channel MOS transistor N2 of the output stage 200, a second P-channel MOS transistor P22, a gate of which is connected to a second input terminal 28, a drain of which is connected to ground VSS, and a source of which is connected to a gate of the first N-channel MOS transistor N1 of the output stage 200, a third P-channel MOS transistor P23, a source of which is connected to the first power supply VDDI of the driver circuit 110, a gate of which is connected to a second power supply 29 of the driver circuit 110, and a drain of which is connected to a gate of the second N-channel MOS transistor N2 of the output stage 200, and a fourth P-channel MOS transistor P24, a source of which is connected to the first power supply VDDI of the driver circuit 110, a gate of which is connected to the second power supply 29 of the driver circuit 110, and a drain of which is connected to a gate of the first N-channel MOS transistor N1 of said output stage 200.

In the case of above-noted circuit, second power supply 29 of said driver circuit 110 is formed by a fifth P-channel MOS transistor P25, a source of which is connected to the first power supply VDDI of the driver circuit 110 and a gate of which is connected to ground VSS, a sixth P-channel MOS transistor P26, a source of which is connected to the first power supply VDDI of the driver circuit 110, a drain of which is connected to a drain of the fifth P-channel MOS transistor P25, and a gate of which is set to a prescribed potential 30, a first N-channel MOS transistor N24, a drain and a gate of which are connected to the drain of the fifth P-channel MOS transistors P25, and a source of which is connected to ground VSS, a second N-channel MOS transistor N25, a source of which is connected to ground VSS and a gate of which is connected to a gate of the first N-channel MOS transistor N24 of the driver circuit 110, and a seventh P-channel MOS transistor P27, a source of which is connected to the first power supply VDDI of the driver circuit 110, and a drain and a gate of which are connected to a drain of the second N-channel MOS transistor N25 and also connected to gates of the third and fourth P-channel MOS transistors P23, P24.

The second power supply 29 is configured so as to control the current of the third and fourth P-channel MOS transistors P23 and P24 in response to variation in the voltage of the first power supply VDDI of the driver circuit 110.

The second embodiment of the present invention is described in further detail below.

The input terminal 27 is a positive-phase input terminal, and the input terminal 28 is an inverted-phase input terminal, the input high logic level of which is at the same potential as the power supply VDDI of the internal circuit region, and the input low logic level of which is at the ground potential. The transistor N3 is connected to the other transistors in current mirror fashion, and the gate voltage thereof is set so that a prescribed constant current flows. A constant voltage is input to the terminal 29 of the transistors P23 and P24, and a prescribed constant current flows in the transistor P23 and P24. The transistors P21 and P22 are connected so as to form a PMOS source follower, and when a high level is applied to the positive-phase input terminal 27 and a low level is applied to the inverted-phase input terminal 28, the drain voltages of the transistors P21 and P22 output voltages shifted a voltage input from the input terminals by the value of VGS of the P-channel MOS transistors, the output stage receiving these differential signals, so that the transistor N1 is switched off and the transistor N2 is switched on. Therefore, the constant current I1 established by the transistor N3 flows in the transistor N2, so that the positive-phase output terminal 1 is at the same potential as the power supply VDDE, causing a high logic level output, and the inverted-phase output terminal 2 is at (VDDE−I1×R4), causing a low logic level output.

Thus, in the second embodiment as well, the low logic level signal input to the positive-phase input terminal 27 and the inverted-phase input terminal 28 is shifted upward by the voltages across the gates and sources of the transistors P21 and P22, thereby preventing a drop in the drain voltage of the transistor N3.

### Third Embodiment

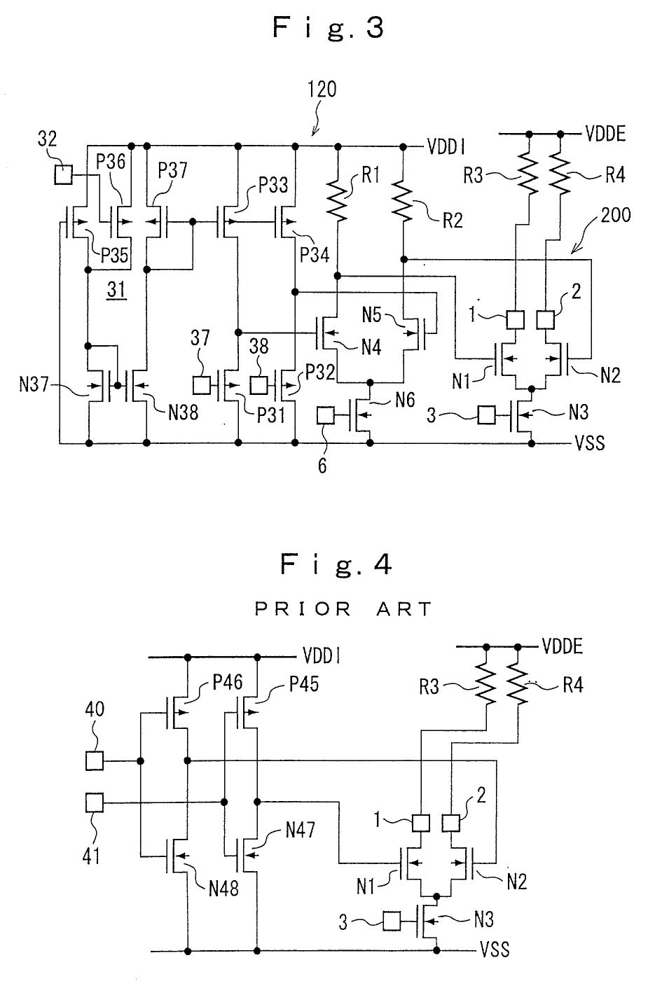

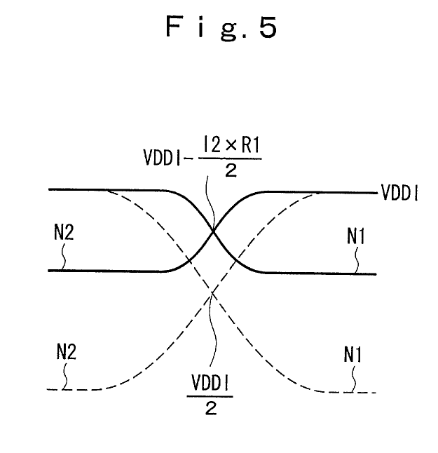

FIG. 3 is a circuit diagram showing a driver circuit according to a third embodiment of the present invention.

FIG. 3 shows a driver circuit 120 of an output stage 200 comprising a first power supply VDDE, a first N-channel MOS transistor N1, a drain of which is connected to a first output terminal 1, a second N-channel MOS transistor N2, a drain of which is connected to a second output terminal 2, and a third N-channel MOS transistor N3, a source of which is connected to ground VSS, a gate of which is connected to a second power supply 3, and a drain of which is connected to a source of the first N-channel MOS transistor N1 and a source of the second N-channel MOS transistor N2, a first resistor R3 connected between the first power supply VDDE and the drain of the first N-channel MOS transistor N1, a second resistor R4 connected between the first power supply VDDE and the drain of the second N-channel MOS transistor N2, wherein the driver circuit 120 comprising; a first power supply VDDI of the driver circuit 120, a first resistor R1 connected between the first power supply VDDI of the driver circuit 120 and a gate of the first N-channel MOS transistor N1 of the output stage 120, a second resistor R2 connected between the first power supply VDDI of the driver circuit 120 and a gate of the second N-channel MOS transistor N2, a first N-channel MOS transistor N4, a drain of which is connected to a gate of the first N-channel MOS transistor N1 of the output stage 200, a second N-channel MOS transistor N5, a drain of which is connected to a gate of the second N-channel MOS transistor N2 of the output stage 200, a third N-channel MOS transistor N6, a source of which is connected to ground VSS, a gate of which is connected to a second power supply 6 of the driver circuit 120, and a drain of which is connected to a source of the first N-channel MOS transistor N4 of the driver circuit 120 and a source of the second N-channel MOS transistor N5 of the driver circuit 120, a first P-channel MOS transistor P37, a gate of which is connected to a first input terminal 37, a drain of which is connected to ground VSS, and a source of which is connected to a gate of the first N-channel MOS transistor N4 of the driver circuit 120, a second P-channel MOS transistor P32, a gate of which is connected to a second input terminal 38, a drain of which is connected to ground VSS, and a source of which is connected to a gate of the second N-channel MOS transistor N5 of the driver circuit 120, a third P-channel MOS transistor P33, a source of which is connected to the first power supply VDDI of the driver circuit 120, a gate of which is connected to a third power supply 31 of the driver circuit 120, and a drain of which is connected to a gate of the first N-channel MOS transistor N4 of the driver circuit 120, and a fourth P-channel MOS transistor P34, a source of which is connected to the first power supply VDDI of the driver circuit 120, a gate of which is connected to the third power supply 31 of the driver circuit 120, and a drain of which is connected to a gate of the second N-channel MOS transistor N5 of the driver circuit 120.

In the case of the above-noted circuit, the third power supply 31 is formed by a fifth P-channel MOS transistor P35, the source of which is connected to the first power supply VDDI of the driver circuit 120 and the gate of which is grounded, a sixth P-channel MOS transistor P36, the source of which is connected to the first power supply VDDI of the driver circuit 120, the drain of which is connected to the drain of the fifth P-channel MOS transistor P35, and the gate potential of which is set to a prescribed potential 32, a fourth N-channel MOS transistor N37, the source of which is connected to ground VSS, the drain and gate of which are connected to the drains of the fifth and sixth P-channel MOS transistors P35 and P36, a fifth N-channel MOS transistor N38, the source of which is grounded and the gate of which is connected to the gate of the fourth N-channel NMOS transistor N37, and a seventh P-channel MOS transistor P37, the source of which is connected to the first power supply VDDI of the driver circuit 120, the drain and gate of which are connected to the drain of the fifth N-channel NMOS transistor N38 and also connected to the gates of the third and fourth P-channel MOS transistors P33 and P34.

The third embodiment of the present invention is described in further detail below.

The input terminal 37 is a positive-phase input terminal and the input terminal 38 is an inverted-phase input terminal, the input high level of which is at the same potential as the power supply VDDI, and the input low logic level of which is at the ground potential. The transistors N3 and N6 are connected to the other transistors in current mirror fashion, and the gate voltages thereof are set so that a prescribed constant-current flow. The transistor P36 is connected to other transistors in current mirror fashion, and the gate voltage thereof is set so that a prescribed constant current flows. Because the gate of the transistor P35 is grounded, if the power supply voltage VDDI becomes high, more current flows, and if the power supply VDDI becomes low, less current flows. The total of the drain currents of the transistors P35 and P36 flows in the transistor N37. According to the circuit formed by transistor N37, N38, P33, P34, the current flowing in the transistor N37 is equal to the current of the transistor N38, P33, P34 because of a current mirror connection. The transistors P31 and P32 are connected so as to form a PMOS source follower circuit, and when a high level is applied to the positive-phase input terminal 37 and a low level is applied to the inverted-phase input terminal 38, the drain voltages of the transistors P31 and P32 is output voltages shifted a voltage input from the input terminals by the value of VGS of the P-channel MOS transistors. Therefore, the transistor N4 is switched on and the transistor N5 is switched off. The constant current I2 established by the transistor N6 flows in the transistor N4, so that the drain potential of the transistor N4 is (VDDI−I2×R1). Because there is no current flowing in the transistor N5, the drain potential of the transistor N5 is VDDI, so that the transistor N1 is of, and the transistor N2 is on. Because the constant current I1 established by the transistor N3 flows in the transistor N2, the positive-phase output terminal 1 is at the same potential as VDDI, thereby outputting a high logic level, and the inverted-phase output terminal 2 is at (VDDE−I1×R4), thereby outputting a low logic level. To achieve high-speed operation, the size of the switching transistors N1 and N2 in the output stage increases, making it necessary to also make the current of the differential circuit for the second level shift circuit formed by the transistors N4 and N5 large, so that when common-mode voltage is applied, there occurs the same problem in the second level-shifting circuit as when there is a drop in the drain potential of the constant current supplying transistor N3 in the output stage. The first level-shifting circuit formed by a PMOS source follower operates so as to limit the change in the drain potential of the constant current supplying transistors N6 during differential operation. If the power supply voltage of the second power supply VDDI is low, the transistors P33 and P34 could operate in the non-saturated region, so that the signal amplitude output at the sources of the transistors P31 and P32 is reduced. When the power supply voltage of the second power supply VDDI is high, because of the increased signal amplitude input to the input terminals 37 and 38, although a dependency on the power supply voltage is exhibited in the input amplitude of transistors N4 and N5, the transistor P35 acts to prevent this, and if the power supply voltage is made high, a large current flows in the transistors P33 and P34, thereby making the source potential of the transistors P31 and P32 high, so as to establish small-amplitude operation of the present invention.

The present invention as described above achieves a number of effects.

The first effect is to prevent operation of the constant-current supplying transistors in the output stage in the non-saturated region. The reason for this is that the potential of a signal input to the switching transistors of the output stage is made high, so as to prevent a drop in the drain potential of the constant current supplying transistors.

The second effect achieved by the present invention is the limiting of variation of the drain potential of the constant-current supplying transistors during switching, thereby preventing the transistors of the output stage from being on simultaneously, or the occurrence of excessive current for charging the drain capacitance, the result being the achievement of a high-quality waveform. The reason for this is that, by making the change in the potential of the input signal applied to the switching transistors of the output stage small and low, the drain potential variation of the constant-current supplying transistors of the output stage between differential operation and common-mode operation is made small.

What is claimed is:

1. A driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of said first N-channel MOS transistor and a source of said second N-channel MOS transistor, a first resistor connected between said first power supply and said drain of said first N-channel MOS transistor, a second resistor connected between said first power supply and said drain of said second N-channel MOS transistor, wherein said driver circuit comprising;
a first power supply of said driver circuit,
a first resistor connected between said first power supply of said driver circuit and a gate of said first N-channel MOS transistor of said output stage,
a second resistor connected between said first power supply of said driver circuit and a gate of said second N-channel MOS transistor,
a first N-channel MOS transistor, a drain of which is connected to a gate of said first N-channel MOS transistor of said output stage, and a gate of which is connected to a first input terminal,
a second N-channel MOS transistor, a drain of which is connected to a gate of said second N-channel MOS transistor of said output stage, and a gate of which is connected to a second input terminal, and
a third N-channel MOS transistor, a source of which is connected to ground, a gate of which is connected to a second power supply of said driver circuit, and a drain of which is connected to a source of said first N-channel MOS transistor of said driver circuit and a source of said second N-channel MOS transistor of said driver circuit.

2. A driver circuit according to claim 1, wherein a potential of said first power supply of said driver circuit is lower than that of said first power supply of said output stage.

3. A driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of said first N-channel MOS transistor and a source of said second N-channel MOS transistor, a first resistor connected between said first power supply and said drain of said first N-channel MOS transistor, a second resistor connected between said first power supply and said drain of said second N-channel MOS transistor, wherein said driver circuit comprising;
a first power supply of said driver circuit, a potential of which is lower than that of said first power supply of said output stage,
a first resistor connected between said first power supply of said driver circuit and a gate of said first N-channel MOS transistor of said output stage,
a second resistor connected between said first power supply of said driver circuit and a gate of said second N-channel MOS transistor,
a first N-channel MOS transistor, a drain of which is connected to a gate of said first N-channel MOS transistor of said output stage, and a gate of which is connected to a first input terminal,
a second N-channel MOS transistor, a drain of which is connected to a gate of said second N-channel MOS transistor of said output stage, and a gate of which is connected to a second input terminal, and
a third N-channel MOS transistor, a source of which is connected to ground, a gate of which is connected to a second power supply of said driver circuit, and a drain of which is connected to a source of said first N-channel MOS transistor of said driver circuit and a source of said second N-channel MOS transistor of said driver circuit.

4. A driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of said first N-channel MOS transistor and a source of said second N-channel MOS transistor, a first resistor connected between said first power supply and said drain of said first N-channel MOS transistor, a second resistor connected between said first power supply and said drain of said second N-channel MOS transistor, wherein said driver circuit comprising;
a first power supply of said driver circuit,
a first P-channel MOS transistor, a gate of which is connected to a first input terminal, a drain of which is connected to ground, and a source of which is connected to a gate of said second N-channel MOS transistor of said output stage,
a second P-channel MOS transistor, a gate of which is connected to a second input terminal, a drain of which is connected to ground, and a source of which is connected to a gate of said first N-channel MOS transistor of said output stage,
a third P-channel MOS transistor, a source of which is connected to said first power supply of said driver circuit, a gate of which is connected to a second power supply of said driver circuit, and a drain of which is connected to a gate of said second N-channel MOS transistor of said output stage, and
a fourth P-channel MOS transistor, a source of which is connected to said first power supply of said driver circuit, a gate of which is connected to said second power supply of said driver circuit, and a drain of which is connected to a gate of said first N-channel MOS transistor of said output stage.

5. A driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of said first N-channel MOS transistor and a source of said second N-channel MOS transistor, a first resistor connected between said first power supply and said drain of said first N-channel MOS transistor, a second resistor connected between said first power supply and said drain of said second N-channel MOS transistor, wherein said driver circuit comprising;
a first power supply of said driver circuit, a potential of which is lower than that of said first power supply of said output stage,
a first P-channel MOS transistor, a gate of which is connected to a first input terminal, a drain of which is connected to ground, and a source of which is connected to a gate of said second N-channel MOS transistor of said output stage,
a second P-channel MOS transistor, a gate of which is connected to a second input terminal, a drain of which is connected to ground, and a source of which is connected to a gate of said first N-channel MOS transistor of said output stage,
a third P-channel MOS transistor, a source of which is connected to said first power supply of said driver circuit, a gate of which is connected to a second power supply of said driver circuit, and a drain of which is connected to a gate of said second N-channel MOS transistor of said output stage, and
a fourth P-channel MOS transistor, a source of which is connected to said first power supply of said driver circuit, a gate of which is connected to said second power supply of said driver circuit, and a drain of which is connected to a gate of said first N-channel MOS transistor of said output stage.

6. A driver circuit according to claim 5, wherein said second power supply of said driver circuit comprising;
a fifth P-channel MOS transistor, a source of which is connected to said first power supply of said driver circuit and a gate of which is connected to ground,
a sixth P-channel MOS transistor, a source of which is connected to said first power supply of said driver circuit, a drain of which is connected to a drain of said fifth P-channel MOS transistor, and a gate of which is set to a prescribed potential,
a first N-channel MOS transistor, a drain and a gate of which are connected to said drain of said fifth P-channel MOS transistors, and a source of which is connected to ground,
a second N-channel MOS transistor, a source of which is connected to ground and a gate of which is connected to a gate of said first N-channel MOS transistor of said driver circuit, and
a seventh P-channel MOS transistor, a source of which is connected to said first power supply of said driver circuit, and a drain and a gate of which are connected to a drain of said second N-channel MOS transistor and also connected to gates of said third and fourth P-channel MOS transistors.

7. A driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of said first N-channel MOS transistor and a source of said second N-channel MOS transistor, a first resistor connected between said first power supply and said drain of said first N-channel MOS transistor, a second resistor connected between said first power supply and said drain of said second N-channel MOS transistor, wherein said driver circuit comprising;
a first power supply of said driver circuit,
a first resistor connected between said first power supply of said driver circuit and a gate of said first N-channel MOS transistor of said output stage,
a second resistor connected between said first power supply of said driver circuit and a gate of said second N-channel MOS transistor,
a first N-channel MOS transistor, a drain of which is connected to a gate of said first N-channel MOS transistor of said output stage,
a second N-channel MOS transistor, a drain of which is connected to a gate of said second N-channel MOS transistor of said output stage,
a third N-channel MOS transistor, a source of which is connected to ground, a gate of which is connected to a second power supply of said driver circuit, and a drain of which is connected to a source of said first N-channel MOS transistor of said driver circuit and a source of said second N-channel MOS transistor of said driver circuit.
a first P-channel MOS transistor, a gate of which is connected to a first input terminal, a drain of which is connected to ground, and a source of which is connected to a gate of said first N-channel MOS transistor of said driver circuit,
a second P-channel MOS transistor, a gate of which is connected to a second input terminal, a drain of which is connected to ground, and a source of which is connected to a gate of said second N-channel MOS transistor of said driver circuit,
a third P-channel MOS transistor, a source of which is connected to said first power supply of said driver circuit, a gate of which is connected to a third power supply of said driver circuit, and a drain of which is connected to a gate of said first N-channel MOS transistor of said driver circuit, and
a fourth P-channel MOS transistor, a source of which is connected to said first power supply of said driver circuit, a gate of which is connected to said third power supply of said driver circuit, and a drain of which is connected to a gate of said second N-channel MOS transistor of said driver circuit.

8. A driver circuit of an output stage comprising a first power supply, a first N-channel MOS transistor, a drain of which is connected to a first output terminal, a second N-channel MOS transistor, a drain of which is connected to a second output terminal, and a third N-channel MOS transistor, a source of which is connected to ground, a gate of which is connected to a second power supply, and a drain of which is connected to a source of said first N-channel MOS transistor and a source of said second N-channel MOS transistor, a first resistor connected between said first power supply and said drain of said first N-channel MOS transistor, a second resistor connected between said first power supply and said drain of said second N-channel MOS transistor, wherein said driver circuit comprising;
a first power supply of said driver circuit, a potential of which is lower than that of said first power supply of said output stage,
a first resistor connected between said first power supply of said driver circuit and a gate of said first N-channel MOS transistor of said output stage,
a second resistor connected between said first power supply of said driver circuit and a gate of said second N-channel MOS transistor,
a first N-channel MOS transistor, a drain of which is connected to a gate of said first N-channel MOS transistor of said output stage,
a second N-channel MOS transistor, a drain of which is connected to a gate of said second N-channel MOS transistor of said output stage,
a third N-channel MOS transistor, a source of which is connected to ground, a gate of which is connected to a second power supply of said driver circuit, and a drain of which is connected to a source of said first N-channel MOS transistor of said driver circuit and a source of said second N-channel MOS transistor of said driver circuit.
a first P-channel MOS transistor, a gate of which is connected to a first input terminal, a drain of which is connected to ground, and a source of which is connected to a gate of said first N-channel MOS transistor of said driver circuit,
a second P-channel MOS transistor, a gate of which is connected to a second input terminal, a drain of which is connected to ground, and a source of which is connected to a gate of said second N-channel MOS transistor of said driver circuit,
a third P-channel MOS transistor, a source of which is connected to said first power supply of said driver circuit, a gate of which is connected to a second power supply of said driver circuit, and a drain of which is connected to a gate of said first N-channel MOS transistor of said driver circuit, and
a fourth P-channel MOS transistor, a source of which is connected to said first power supply of said driver circuit, a gate of which is connected to said second power supply of said driver circuit, and a drain of which is connected to a gate of said second N-channel MOS transistor of said driver circuit.
